(19) United States
(12) Patent Application Publication
(10) Pub. No.: US 2007/0164456 A1
(43) Pub. Date: Jul. 19, 2007

(54) Repaired extrider dies and repairing method therefor

(75) Inventor: Hitoshi Kanmura, Inabe-gun (JP)

Correspondence Address: NIXON & VANDERHYE, PC, 901 NORTH GLEBE ROAD, 11TH FLOOR, ARLINGTON, VA, 22203, US

(73) Assignee: Denso Corporation, Kariya-city (JP)

(21) Appl. No.: 11/652,123

(22) Filed: Jan. 11, 2007

(30) Foreign Application Priority Data
Jan. 13, 2006 (JP) 2006-006644
Jan. 13, 2006 (JP) 2006-006645

(51) Int. Cl. H01L 23/28; H01L 21/00

(52) U.S. Cl. 257/787; 438/124

(57) ABSTRACT

A method is provided for repairing a die for molding a structure. A die to be repaired has holes for supplying a material, grooves arranged in a lattice form for communicating with the respective holes and for forming the material into a desired shape, and worn-out portions caused by repeated use. In the method, a repairing film is formed on a surface having the grooves and serving as an end face of a die body, through which extrusion is performed, so as to extend onto each corner at an intersecting line between the groove-formed surface and an inner side face of each groove, to restore each worn-out portion. Meanwhile, a material is supplied from the groove-formed surface side utilizing either one or both of PVD and CVD processes. This method readily provides a repaired die with good accuracy, which is excellent in durability and abrasion resistance.

### CROSS-REFERENCE TO RELATED APPLICATION

This application is based on and claims the benefit of priorities from earlier Japanese Patent Application Nos. 2006-006645 and 2006-006644 both filed on Jan. 13, 2006, the descriptions of which are incorporated herein by reference.

### BACKGROUND OF THE INVENTION

1. Technical field of the Invention

The present invention relates to a method for repairing a die for molding a structure utilizing a process of extrusion, and a die repaired by using the repairing method.

2. Related Art

A ceramic honeycomb structure used as an exhaust gas clarifying filter for a vehicle, for example, is manufactured by extruding a material containing a ceramics material by using a die for molding a honeycomb structure (hereinafter referred to simply as a “die”).

Such a die is provided in its body with holes for supplying a material, and grooves arranged in a lattice form for communicating with the supply holes and for molding the material into a honeycomb shape.

When a material is extruded using the die mentioned above, the material flowing through the supply holes and the grooves comes into contact with the die body to produce friction therebetween. The friction produced in this way causes abrasion in the die body. In particular, each corner formed at an intersecting line between a surface where the groove is formed and an inner surface of each groove is likely to suffer from abrasion. Repetition of extrusion may enlarge the portion worn out by the abrasion to deteriorate the dimensional accuracy of the extruded honeycomb structure. Thus, when the dimensional error of the extruded honeycomb structure exceeds a design tolerance, the life of the die comes to an end.

Some methods for repairing a die that has ended its lifetime have been suggested. For example, one repairing method uses electroless nickel plating or hard chromium plating, for example, for treatment of an abrasion portion in a die body. In this case, however, abrasion resistance of the portion treated with such plating is likely to become insufficient.

In order to achieve sufficient abrasion resistance, one method uses a CVD process to form a film having abrasion resistance over the entire surface of a die body (refer to U.S. Pat. Nos. 5,256,449 and 5,328,513 (which are both based on Japanese Patent Laid-Open No. H05-269719)). However, it is difficult to form a film of an even thickness over the entire surface of a die body using a CVD process. Thus, a repaired die tends to suffer from insufficient dimensional accuracy without being able to obtain a honeycomb structure with a desired dimension.

In this way, the conventional methods for repairing dies had difficulty in readily repairing a die with an accurate dimension. Further, a die repaired in this way may not have sufficient durability or abrasion resistance.

### SUMMARY OF THE INVENTION

The present invention has been made in light of the problems provided above, and has as its object to provide a method for repairing a die for molding a structure and to provide a die repaired using the repairing method, which is able to readily and accurately repair a die that has been disabled, through repeated use, to exert accuracy finishing required by a structure to be molded, and which ensures excellent durability and abrasion resistance.

The present invention provides, as one aspect, a method for repairing a used extrusion die being used to form a structural body, the die having a first surface, a lattice-shaped groove thereon, a through-hole which communicates with the groove, and a worn corner where the first surface crosses an inner wall of the groove, the method comprising steps of supplying a material to the first surface, and forming a film on the worn corner with the material.

The present invention provides, as another aspect, a method for manufacturing an extrusion die which is used to extrusion-mold a structural body, the die having a surface with a groove thereon, a through-hole communicating with the groove, and a corner where the surface crosses a wall of the groove, the method comprising steps of rounding for rounding the corner, and forming for forming a film on a rounded corner rounded by the rounding step.

The present invention provides, as still another aspect, a die for extrusion-molding a structural body comprising a surface with a groove thereon, a through-hole communicating with the groove, a rounded corner of the die, the corner where the surface crosses a wall of the groove, and a film being formed on the corner.

### BRIEF DESCRIPTION OF THE DRAWINGS

In the accompanying drawings:

FIG. 1 is a partial perspective sectional view showing a structure of a die before use, according to first, second and third embodiments of the invention;

FIG. 2 is a sectional view taken along line II-II′ of FIG. 1;

FIG. 3 is a sectional view (i.e. an enlarged view of part III of FIG. 2 after use) showing a vicinity of a groove of a die to be repaired, according to the first to the third embodiments of the invention;

FIG. 4 is an explanatory view showing a state where the a die has been secured to a PVD jig, according to the first to the third embodiments;

FIG. 5 is an explanatory view showing an arrangement of a PVD apparatus, according to the first to the third embodiments of the invention;

FIG. 6 is a sectional view showing a vicinity of a groove of a repaired die, according to the first and the second embodiments of the invention;

FIG. 7 is a diagram explaining a relation between a depth “d” from a groove-formed surface along a direction in which a groove extends, and a thickness “t” of a CVD repairing film and a PVD repairing film, according to the first embodiment of the invention;

FIG. 8 is a diagram explaining a relation between a distance L from an inner side face of a groove along a direction in which a groove-formed surface extends, and a thickness “s” of a CVD repairing film and a PVD repairing film, according to the first embodiment of the invention;

FIG. 9 is an explanatory view showing a state where a die has been secured to a CVD jig, according to the second and third embodiments of the invention;

FIG. 10 is an explanatory view showing an arrangement of a CVD apparatus, according to the second and third embodiments of the invention;

FIG. 11 is an explanatory view showing a vicinity of a groove of a repaired die, according to the third embodiment of the invention;

FIG. 12 is a diagram explaining a relation between a depth “d” from a groove-formed surface along a direction in which a groove extends, and a thickness “t” of a repairing film, according to the third embodiment of the invention;

FIG. 13 is a diagram explaining a relation between a distance L from an inner side face of a groove along a direction in which a groove-formed surface extends, and a thickness “s” of a repairing film, according to the third embodiment of the invention;

FIG. 14 is an explanatory view showing a state where a die has been secured to a CVD jig, according to a modification of the third embodiment of the invention;

FIG. 15 is an explanatory view showing a state where a die has been secured to a PVD jig, according to the modification of the third embodiment of the invention;

FIG. 16 is an explanatory view showing a vicinity of a groove of a repaired die, according to the modification of the third embodiment of the invention;

FIG. 17 is a diagram explaining experimental results of a life comparative test of repaired dies according to the first to the third embodiments of the invention; and

FIG. 18 is a schematic diagram showing an enlarged view near an opening of a groove formed on a die surface after forming a film according to the modification of the invention.

### DETAILED DESCRIPTION OF THE PREFERRED EMBODIMENTS

Hereinafter are described first, second and third embodiments of the present invention with reference to the accompanying drawings.

### (Die to be Repaired)

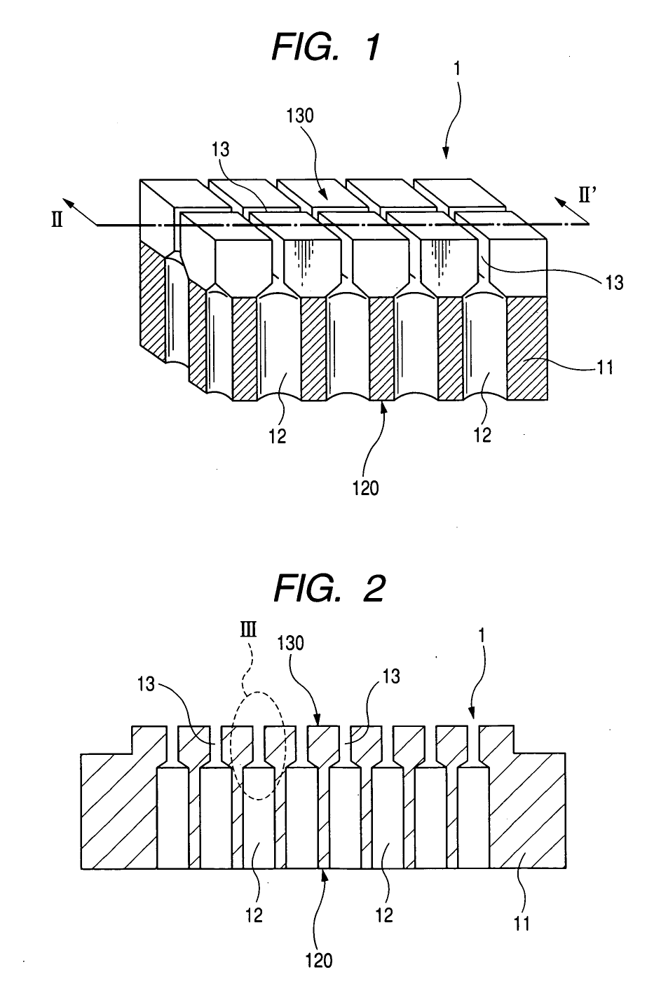

A description is given first, referring to FIGS. 1 to 3, on a die 1 for molding a structure, which die is to be repaired using a method of the present invention. The die 1 described hereinafter is subjected to repairing throughout the first to the third embodiments described later.

FIG. 1 is a partial perspective sectional view of the die 1 which is typically used for molding a structure. FIG. 2 is a sectional view taken along line II-II′ of FIG. 2. FIGS. 1 and 2 each show a state of a die before use.

As shown in FIGS. 1 and 2, the die 1 for molding a structure (hereinafter referred to as “die 1”) before use is made up of a die body 11 in which supply holes 12 and grooves 13 are formed. The die body 11 has a hole-formed surface 120 in which the supply holes 12 are formed and a groove-,formed surface 130 (also referred as a first surface) in which the grooves 13 are formed. The hole-formed surface 120 (also referred as a second surface) serves as a surface for supplying a material to the die body 11. The groove-formed surface 130 is an end face of the die body 11, through which a material is extruded. The die body is made up of an SKD member.

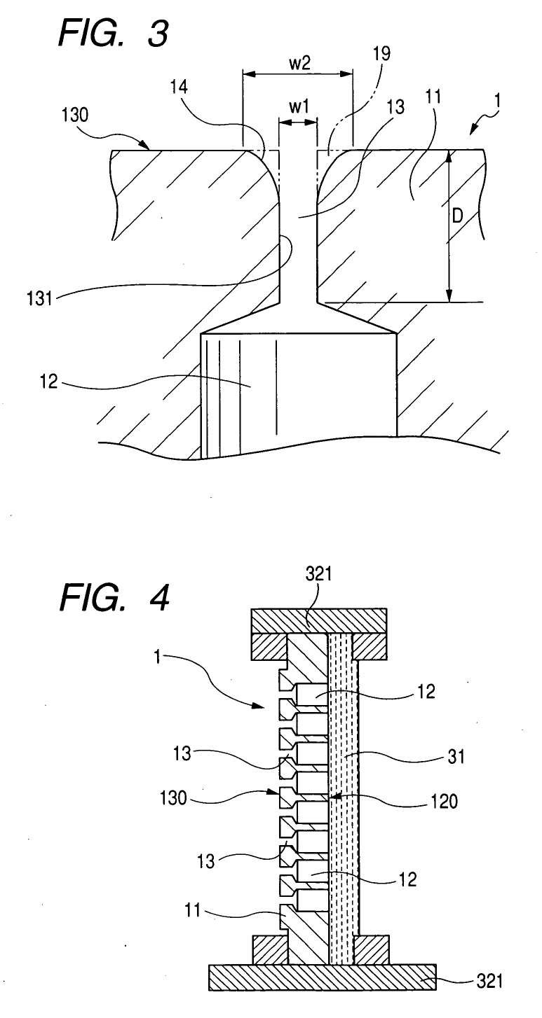

The die 1 after use has the supply holes 12 for supplying a material, and the grooves 13 arranged in a lattice form for communicating with the supply holes 12 and for forming the material into a desired shape. The die 1 after use also has corners 14 each of which is formed at an intersecting line between the groove-formed surface 130 having the grooves 13 and serving as an end face of the die body 11, to which a material is extruded, and an inner side face 131 of each of the grooves 13. As shown in FIG. 3, each of the corners 14 used to have a portion 19 before the die 1 is used, which, however, has disappeared through repeated use (this portion is hereinafter referred to as “worn-out portion 19”). Typically, the corners 14 are largely worn out by being in contact with a material. In FIG. 3, an initial form of the corner 14 is indicated by a broken line. A region defined by the broken line and the solid line in the figure corresponds to the worn-out portion 19. FIG. 3 illustrates a state of portion III of the die shown in FIG. 2. It should be noted that FIG. 2 shows a die before use, and FIG. 3 shows the die after use.

The die 1, which is to be repaired by using the repairing method of the present invention, is used for molding a structure by extruding a material containing a ceramics material, for example. The worn-out portion 19 of the die 1 results from repeated use of the die 1, or repeated extrusion of the material using the die 1. As the abrasion progresses, formation of a structure having an accurate dimension becomes difficult to eventually allowing the die to come to the end of its lifetime.

As shown in FIG. 3, a depth D of the groove 13 is 5 mm. An initial width “w” of the groove 13 before use is 140 μm, and a life-end width of the groove 13 is “w2” 150 μm.

Each of the first to the third embodiments describes a method for repairing the die one by restoring the worn-out portion 19, and a die repaired using the method.

### First Embodiment

A method for repairing the die 1 according to a first embodiment includes supplying a film-forming material onto the worn-out portion 19 from the groove-formed surface 130, and performing a PVD (physical vapor deposition) process to form a repairing film 2. The method will now be explained with reference to FIGS. 4 to 6.

### (1.1 PVD Apparatus)

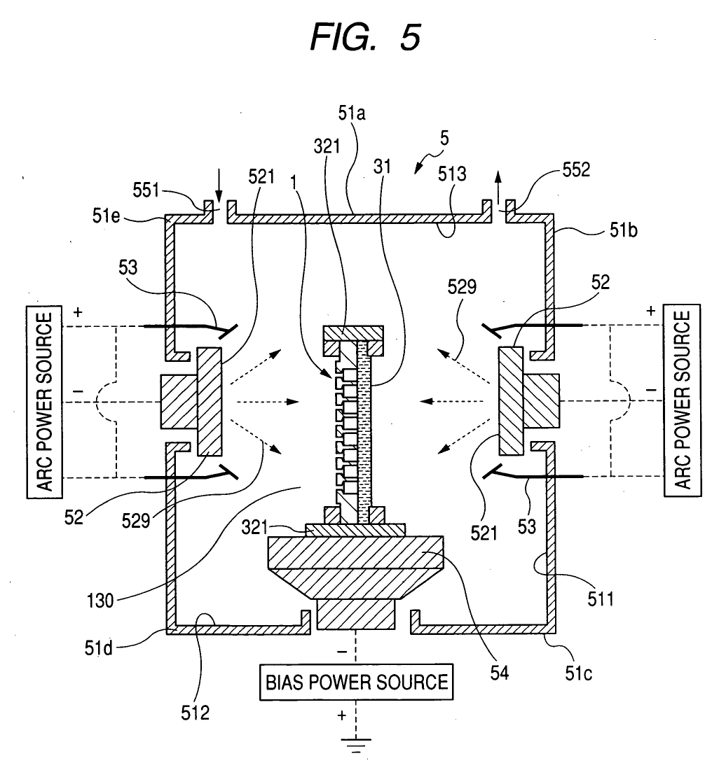

First of all, a PVD apparatus 5 used for the PVD process is explained: As shown in FIG. 5, the PVD apparatus 5 has a cylindrical reactor 51. The reactor 51 is made up of parts 51a, 51b, 51c, 51d and 51e. The reactor 51 has a diameter of 600 mm and a height of 600 mm. A plurality of metal targets 52 are provided to an inner side face 511 of the reactor 51. A pair of anode plates 53 are provided at positions next to a surface 521 of each metal target 52. The pair of anode plates 53 are connected to a plus (+) side of an arc power source, and the metal target 52 is connected to a minus (−) side of the arc power source. In the present embodiment, Cr or Ti is used as a material for constructing the metal target 52.

As shown in FIG. 5, a rotating table 54 which is rotatable about a vertical axis is provided at a bottom 512 of the reactor 51. The rotating table 54 is connected to a bias power source. A top 513 of the reactor 51 is provided with a gas supply port 551 for supplying a reaction gas into the reactor 51 and an exhaust port 552 for exhausting the gas in the reactor 51. The reactor 51 is also provided with a vacuum pump (not shown).

### (1.2 Repairing Method)

The repairing method according to the present embodiment is described below.

Prior to carry out the PVD process, a mask is provided to the die 1 as shown in FIG. 4. Specifically, a masking plate 31 made of graphite, for example, is laid over the hole-formed surface 120 so as to block the supply holes 12. Then, the die 1 and the masking plate 31 are secured to a PVD jig 321. In this way, the hole-formed surface 120 of the die 1 is masked.

Subsequently, the PVD process is carry out for the masked die 1. As shown in FIG. 5, the PVD jig 321 to which the die 1 has been secured is set on the rotating table 54, so that the groove-formed surface 130 of the die 1 faces each of the metal targets 52 as rotated by the rotating table 54. The reactor 51 is then vacuumed, followed by heating. A degree of vacuum in the reactor 51 is 1×10⁻⁶ Torr and a heating temperature is 500° C. Then, N₂, a reaction gas, is supplied to the reactor 51 through the gas supply port 551.

As shown in FIG. 5, with each metal target 52 serving as a cathode, arc discharge is allowed to occur at the surface 521 of each metal target 52. Being encouraged by the energy of arc current (70 to 200 A) generated by the arc discharge, the material constructing each of the metal targets 52 instantaneously evaporates and at the same time turns into metal ions 529, and then flies into the reactor 51. Meanwhile, when a bias voltage is applied to the PVD jig 321 through the rotating table 54 from a bias power source, flying speed of the metal ions 529 is accelerated. The metal ions 529, together with the particles of the reaction gas (N₂), turn into a film-forming material (CrN or TiN in the present embodiment), collide against the groove-formed surface 130 of the die 1, and deposit to form a film. In the present embodiment, a film of an even thickness can be formed because the PVD process is carry out with the rotation of the rotating table 54.

Finally, after cooling the inside of the reactor 51, the atmospheric condition is brought back and then the PVD jig 321 is taken out of the reactor 51. Then, the PVD jig 321 is unsecured from the repaired die 1.

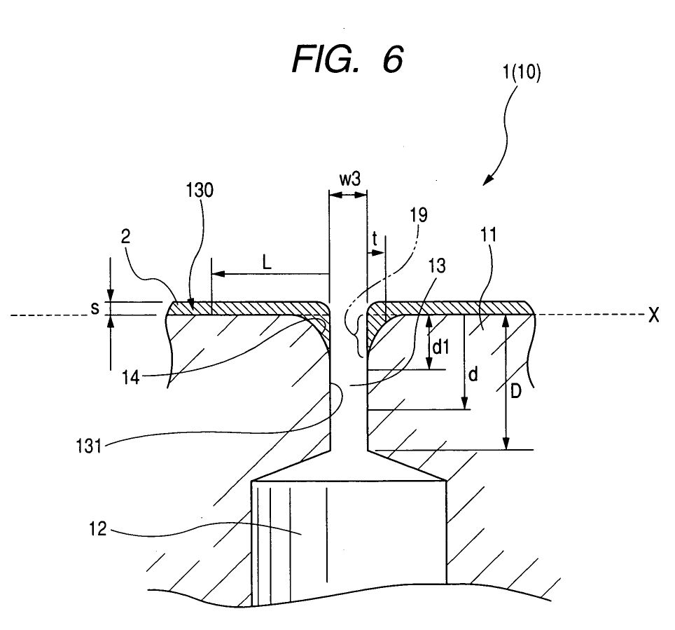

In this way, as shown in FIG. 6, the repairing film 2 is formed on the groove-formed surface 130 so as to extend onto each corner 14 to restore the worn-out portion 19.

In the present embodiment, Cr was used for the metal target 52 to carry out the PVD process, and then the metal target 52 was changed to the one made of Ti to again carry out the PVD process. Accordingly, the repairing film 2 is made up of two layers, i.e. a CrN layer and a TiN layer (not shown).

### (1.3 Repaired Die)

Hereinafter is described a die repaired using the repairing method according to the present embodiment.

As shown in FIG. 6, in the repaired die for molding a structure according to the present embodiment, the repairing film 2 has been formed, through the PVD process, on the groove-formed surface 130 so as to extend onto each corner 14 formed at an intersecting line between the groove-formed surface 130 and the inner side face 131 of the groove 13, so that the worn-out portion 19 is restored.

As mentioned above, the repairing film 2 consists of two layers, i.e. the CrN layer and the TiN layer. The hardness of the repaired film 2 is 2000 HV. As the hardness of the SKD member making up the die body 11 is 500 HV, the hardness of the repairing film is higher than that of the die body 11 by a factor of 4. In order to obtain a repaired die for molding a honeycomb structure having excellent durability and abrasion resistance, a repairing film may preferably have a hardness larger than that of the main body (500 HV). In particular, the repairing film may desirably have a hardness higher than that of the main body by a factor of 1.5 (750 HV) or more to serve as a good coating film for satisfying the required function. The repairing film 2 well satisfies the required function. It should be noted that a width w3 of the groove 13 in the repaired die 1 is 140 μm.

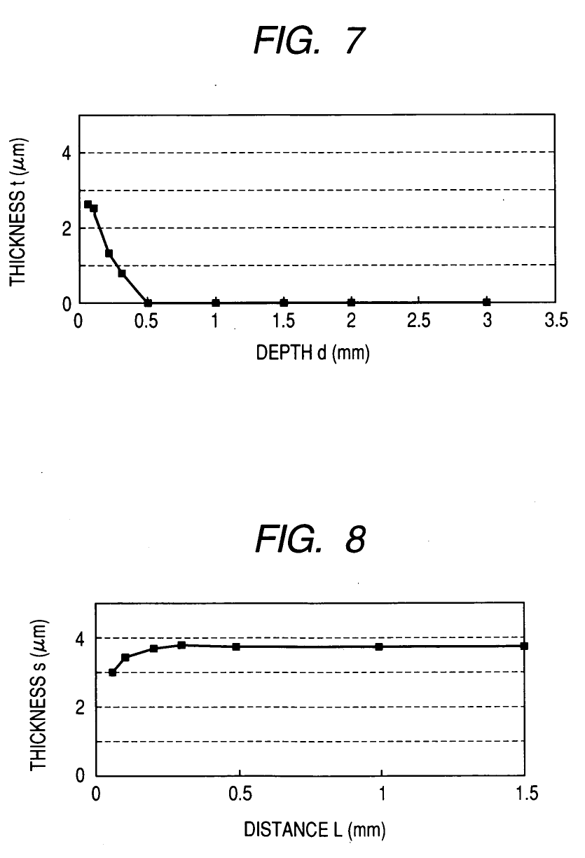

FIG. 7 shows a relation between a depth “d” from the groove-formed surface 130 along a direction in which the groove 13 extends and a thickness “t” of the repairing film 2. Specifically, as shown in FIG. 6, the depth “d” is a distance from the groove-formed surface 130 along a direction of the depth of the groove 13, and the thickness “t” is a thickness of the repairing film 2 along a direction parallel to the groove-formed surface 130.

As can be seen from FIG. 7, at the position of a depth d=0.5 mm, the thickness “t” is close to “0”. This indicates that a region d1 (refer to FIG. 6) in which the repairing film 2 is formed extends within the length or 0.5 mm. In other words, the repairing film 2 is formed in a region which is equal to or smaller than one tenth of a depth D (=5 mm) of the groove 13. It should be appreciated that the region d1 for forming the repairing film 2 is to extend from the groove-formed surface 130 to the point where the thickness “t” of the repairing film 2 is substantially “0”.

FIG. 8 shows a relation between a distance L from the inner side face 131 of the groove 13 along a direction in which the groove-formed surface 130 extends (refer to FIG. 6), and a thickness “s” of the repairing film 2. Specifically, as shown in FIG. 6, the distance L is a distance along a direction stepping away from the inner side face 131 of the groove 13. The thickness “s” is a thickness of the repairing film 2 which is formed in a direction opposite to the depth of the groove 13. It should be noted that the depth of the groove 13 is measured with the groove-formed surface 130 before use as a reference surface X. As can be seen from FIG. 8, the thickness of the repairing film 2 falls within the range of 3 to 4 μm.

### (1.4 Advantages)

The following is a description on the advantages of the repairing method according to the present embodiment.

In the method for repairing the die 1 for molding a structure, the repairing film 2 is formed, through the PVD process, on the groove-formed surface 130 so as to extend onto each of the corners 14 to restore the worn-out portion 19, as described above. Particularly, the repairing film 2 is formed, through the PVD process, only on the side of the groove-formed surface 130 which serves as a surface for extruding a material and plays the most important roll for determining the moldability and dimensional accuracy of a structure.

Thus, in comparison with the conventional repairing method in which a repairing process is carried out with respect to the entire die, the inventive repairing process can be readily and efficiently carried out, and the repairing film 2 can be formed with good accuracy. In addition, film-forming accuracy of the PVD process is so high that the repairing film 2 can be formed with much higher accuracy than in the conventional method. Further, the PVD process can form so thick a film that the repairing process for the die 1 can be performed more efficiently.

As described above, the worn-out portion 19 of each corner 14 can be readily restored with good accuracy. In other words, the life-ended die 1 can be repaired to an extent that the repaired die 1 can mold a structure whose accuracy is equivalent to that of the structure molded by the initial-state die 1.

The repairing film 2 formed by the PVD process has high density and high hardness. By forming such a repairing film on the groove-formed surface 130 for extruding a material therefrom, so as to extend onto each corner 14 tending to suffer from abrasion to thereby restore the worn-out portion 19, the repaired die 1 can effectively achieve excellent durability and abrasion resistance.

As mentioned above, the repairing film 2 of the present embodiment is made up of multiple layers of TiN and CrN, and the hardness of the repairing film 2 is 2000 HV, which is higher than that of the die body 11 by a factor of 4. This means that the repairing film 2 becomes very hard, whereby the repaired die 1 can achieve sufficient durability and abrasion resistance.

The repairing film 2 may alternatively be made up of a single layer of TiN or CrN. A single layer of TiN or a single layer of CrN is still capable of maintaining hardness to a degree of 500 HV or higher, preferably 750 HV or more, as described above, which is the hardness required for serving as a good coating film.

The repairing film 2 is formed depthwise of each groove 13 starting from the groove-formed surface 130, so as to extend within a region which is one tenth or less of the depth D of the groove 13. This exerts an effect of suppressing unevenness in the width of the grooves 13 in the repaired die 1. As a result, the dimensional accuracy of a structure molded by the repaired die 1 can be enhanced.

As described above, in the method for repairing a die according to the present embodiment, a die for molding a structure can be readily repaired with good accuracy, and thus a repaired die for molding a structure may exert excellent durability and abrasion resistance.

### (1.5 Modification)

In the first embodiment, the side of the hole-formed surface 120 of the die body 11 has been masked because a plurality of metal targets 52 have been provided in the PVD apparatus 5. Alternatively, no mask may be provided to the die 1 in the case where, for example, a single metal target 52 is provided, with the die 1 being set so that the metal target 52 and the groove-formed surface 130 of the die 1 face with each other and with the relative position of the both being fixed while the PVD process is carried out.

Although Cr or Ti has been used for the metal target 52 in the first embodiment, the repairing film 2 can be formed using other metal.

### Second Embodiment

Referring now to FIGS. 1-3, 6-8, 9 and 10, hereinafter is described a method for repairing a die for molding a structure and a die repaired by using a repairing method according to a second embodiment of the invention. In the present embodiment, the identical or similar components or processes are given the same references for the sake of simplification or omission of explanation.

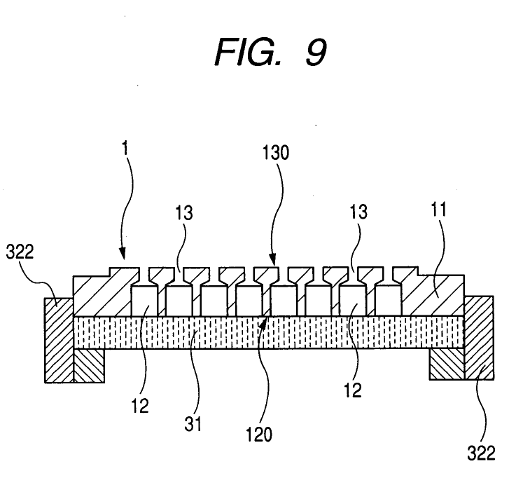

As shown in FIG. 9, in the method for repairing the die 1 according to the present embodiment, a mask is provided to the hole-formed surface 120 formed with the supply holes and serving as a surface for supplying a material to the die body 11, so that the supply holes 12 are blocked. Subsequently, a film-forming material is supplied from the side of the groove-formed surface 130 formed with the grooves 13 and serving as an end surface of the die body 11, through which a material is extruded, followed by carrying out a CVD (chemical vapor deposition) process, so that the repairing film 2 is formed on the groove-formed surface 130, extending onto each corner 14 at the intersecting line between the groove-formed surface 130 and the inner side face 131 of the groove 13, thereby restoring a worn-out portion (worn-out portion 19).

It should be appreciated that the die 1 repaired using the repairing method of the present embodiment has the same quality and shape (refer to FIGS. 1 to 3) as those of the die 1 repaired in the first embodiment.

### (2.1 CVD Apparatus)

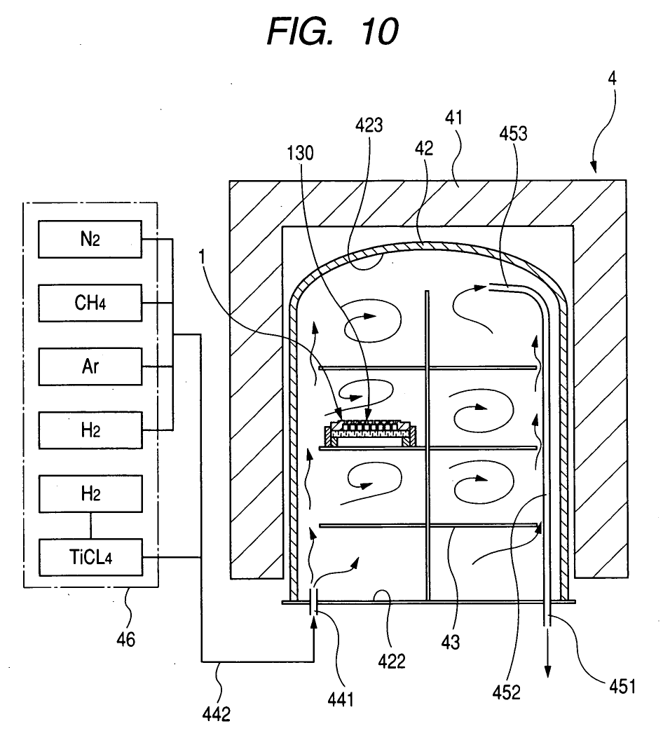

With reference to FIG. 10, a CVD apparatus 4 used for the CVD process is described below.

The CVD apparatus 4 has a cylindrical reaction furnace 41 with an open bottom and has a diameter of 450 mm and a height of 700 mm. A box-shaped reactor 42 is disposed in the reaction furnace 41. The reactor 42 is provided therein with a shelf 43 in which a plurality of chambers are defined for locating the dies 1 to be subjected to the CVD process.

A gas supply port 441 for providing a reaction gas into the reactor 42 is provided at a bottom 422 of the reactor 42. The gas supply port 441 is connected to an externally provided gas supply apparatus 46 through a gas supply pipe 442. The CVD apparatus 4 is arranged in such a way that the reaction gas can be supplied into the reactor 42 from the gas supply apparatus 46. In the present embodiment, TiCl₄, H₂, Ar, CH₄ or N₂ is used as a reaction gas to be supplied from the gas supply apparatus 46.

An exhaust port 451 for exhausting a gas out of the reactor 42 is provided at the bottom 422 of the reactor 42. The exhaust port 451 is connected to an exhaust pipe 452 which extends from the proximity of a top 423 of the reactor 42 to the bottom 422. The CVD apparatus 4 is arranged such a way that the gas in the reactor 42 can be discharged from the exhaust port 451 after being sucked from a suction port 453.

### (2.2 Repairing Method)

The repairing method of the present embodiment will now be described in detail below.

Prior to carrying out the CVD process, a mask is provided to the die 1. As shown in FIG. 9, the masking plate 31 made of graphite, for example, is laid over the hole-formed surface 120 so as to block the supply holes 12. Then, the die 1 and the masking plate 31 are secured to a CVD jig 322. In this way, the hole-formed surface 120 of the die 1 is masked.

Subsequently, the CVD process is carried out for the masked die 1. As shown in FIG. 10, the CVD jig 322 to which the die 1 has been secured is set on the shelf 43, so that the groove-formed surface 130 of the die 1 faces the top 423 of the reactor 42 and that the reaction gas is readily brought into contact with the groove-formed surface 130 of the die 1. Then, the inside of the reactor 42 is heated up to 900 to 1000° C., followed by supplying TiCl₄, H₂, Ar, CH₄ and N₂ as reaction gases into the reactor 42 from the gas supply apparatus 46.

As shown in FIG. 10, the die body 11 heated up to high temperature comes into contact with the reaction gases circulating in the reactor 42 to cause chemical reaction above the groove-formed surface 130 of the die body 11. Thus composed film-forming materials (TiC, TICN and TiN in the present embodiment) are deposited on the groove-formed surface 130 to form a film.

Finally, the inside of the reactor 42 is cooled down to take out therefrom the CVD jig 322. Then, the CVD jig 322 is unsecured from the repaired die 1.

As described above, the repairing film 2 is formed, as in the first embodiment, on the groove-formed surface 130 so as to extend onto each corner 14 to restore the worn-out portion 19 as shown in FIG. 6. In the present embodiment, the repairing film 2 is made up of three layers, i.e. a TiC layer, a TICN layer and a TiN layer (not shown).

### (2.3 Repaired Die)

Hereinafter is described the die 1 repaired by the repairing method of the present embodiment.

As shown in FIG. 6, the repairing film 2 is formed by utilizing the CVD process on the groove-formed surface 130 so as to extend onto each corner 14 to restore the worn-out portion 19 in the repaired die 1 for molding a structure.

As described above, the repairing film 2 is made up of three layers, i.e. the TiC layer, the TiCN layer and the TiN layer. The hardness of the repairing film 2 is 2000 HV, which is higher than that of the die body 11 by a factor of 4. A width w3 of each groove 13 is 140 μm.

The physical characteristics of the repairing film obtained in the second embodiment are substantially the same as those of the repairing film in the first embodiment (refer to FIGS. 6 to 8).

### (2.4 Advantages)

The following is a description on the advantages of the repairing method according to the present embodiment.

In the method for repairing the die 1 for molding a structure according to the present embodiment, the repairing film 2 is formed, through the CVD process, only on the side of the groove-formed surface 130, which serves as a surface for extruding a material in molding a structure and plays the most important roll for determining the moldability and dimensional accuracy of the structure.

Thus, in comparison with the conventional method in which a repairing process is given to the entire die, the die 1 can be efficiently repaired by the inventive method, and at the same time, the repairing film 2 can be formed with good accuracy.

As described above, the worn-out portion 19 of each corner 14 can be readily restored with good accuracy. In other words, the life-ended die 1 can be repaired to an extent that the repaired die 1 can mold a structure whose accuracy is equivalent to that of the structure molded by the initial-state die 1. The repairing film 2 formed by the CVD process has high density and high hardness. By forming such a repairing film on the groove-formed surface 130 for extruding a material therefrom, so as to extend onto each corner 14 tending to cause abrasion to thereby restore the worn-out portion 19, the repaired die 1 can effectively achieve excellent durability and abrasion resistance.

The CVD process has an effect of enhancing adhesion of the repairing film to a base member (which corresponds to the die body 11 in the present embodiment), and thus much more excellent durability can be achieved.

Further, as described above, the repairing film 2 is made up of multiple layers of TiC, TiCN and TiN. This means that the repairing film 2 is turned into one having higher hardness, whereby the repaired die 1 can achieve much more excellent durability and abrasion resistance.

It should be appreciated that other advantages are the same as those in the first embodiment.

### (2.5 Modification)

In the second embodiment, the repairing film 2 has been made up of the multiple layers of TiC, TiCN and TiN. Alternatively, the repairing film 2 may be structured by a single layer of TiC, TiCN or TiN. Alternatively, the repairing film 2 may be structured by two layers formed of any combination of two materials among TiC, TiCN and TiN. In these alternatives as well, it is possible to obtain a repairing film having a hardness of 500 HV, preferably 750 HV or more, which is the hardness required as a good coating film as described above.

### 3. Third Embodiment

Referring now to FIGS. 1-5 and 10-13, hereinafter is described a method for repairing a die for molding a structure, and a die repaired by using the repairing method, according to a third embodiment of the present invention. In the present embodiment, the identical or similar components or processes are given the same references for the sake of simplification or omission of explanation.

In the method for repairing the die 1 according to the present embodiment, a CVD repairing film 21 is formed by using the CVD process on the groove-formed surface 130 formed with the grooves 13 and serving as and end surface of the die body 11, through which extrusion is performed, the CVD repairing film 21 extending onto each corner 14 at an intersecting line between the groove-formed surface 130 and the inner side face 131 of each groove 13 (refer to FIG. 3) to make up for the worn-out portion 19. Subsequently, a film-forming material is supplied from the side of the groove-formed surface 30 onto the CVD repairing film 21 that has been formed on the groove-formed surface 130 so as to extend onto the corner 14. Then the PVD process is carried out to thereby form a PVD repairing film 22 on the CVD repairing film 21 to make up for the worn-out portion 19. In this way, the worn-out portion 19 at each of the corners 14 can be restored.

### (3.1 CVD Apparatus and PVD Apparatus)

It should be appreciated that the CVD apparatus and the PVD apparatus used in the third embodiment are the same as the ones used in the second embodiment and the first embodiment, respectively.

### (3.2 Repairing Method)

The repairing method of the present embodiment is described in detail below.

After masking the die 1, the CVD process is carried out.

As shown in FIG. 9, the masking plate 31 made of graphite, for example, is laid over the hole-formed surface 120 so as to block the supply holes 12. Then, the die 1 and the masking plate 31 are secured to the CVD jig 322. In this way, the hole-formed surface 120 of the die 1 is masked.

Then, as shown in FIG. 10, the CVD jig 322 to which the die 1 is secured is set on the shelf 43, so that the groove-formed surface 130 of the die 1 faces the top 423 of the reactor 42 and that the reaction gas is readily brought into contact with the groove-formed surface 130 of the die 1. Then, the inside of the reactor 42 is heated up to 900 to 1000° C., followed by supplying TiCl₄, H₂, Ar, CH₄ and N₂ as reaction gases into the reactor 42 from the gas supply apparatus 46.

As shown in FIG. 10, the die body 11 heated up to high temperature comes into contact with the reaction gases circulating in the reactor 42 to cause chemical reaction above the groove-formed surface 130 of the die body 11. Thus formed film-forming materials (TiC, TiCN and TiN in the present embodiment) are deposited on the groove-formed surface 130 to form a film.

Finally, the inside of the reactor 42 is cooled down to take out therefrom the CVD jig 322. Then, the CVD jig 322 is unsecured from the repaired die 1. Thus, the CVD repairing film 21 is formed, as shown in FIG. 8, on the groove-formed surface 130 so as to extend onto each corner 14 to restore the worn-out portion 19. In the present embodiment, the CVD repairing film 21 is made up of three layers, i.e. a TiC layer, a TiCN layer and a TiN layer (not shown).

Subsequently, after masking the die 1 that has been subjected to the CVD process, the PVD process is carried out. As shown in FIG. 4, the masking plate 31 made up of graphite, for example, is laid over the hole-formed surface 120 so as to block the supply holes 12. Then, the die 1 and the masking plate 31 are secured to the PVD jig 321. In this way, the side of the hole-formed surface 120 of the die 1 is masked.

Then, as shown in FIG. 5, the PVD jig 321 to which the die 1 is secured is set on the rotating table 54, so that the groove-formed surface 130 of the die 1 faces each of the metal targets 52 as the rotating table 54 rotates. The reactor 51 is then heated after its inside has been vacuumed. A degree of vacuuming the inside of the reactor 51 is 1×10⁻⁶ Torr and the heating temperature is 500° C. As a reaction gas, N₂ is supplied into the reactor 51 from the gas supply port 551.

As shown in FIG. 5, with each metal target 52 serving as a cathode, arc discharge is allowed to occur at the surface 521 of each metal target 52. Being encouraged by the energy of arc current (70 to 200 A) generated by the arc discharge, the material constructing each of the metal targets 52 instantaneously evaporates and at the same time turns into metal ions 529, and then flies into the reactor 51. Meanwhile, when a bias voltage is applied to the PVD jig 321 through the rotating table 54 from a bias power source, the speed of the metal ions 529 that have flown out is accelerated. The metal ions 529, together with the particles of the reaction gas (N₂), turn into film-forming materials (CrN and TiN in the present example), collide against the groove-formed surface 130 of the die 1, and deposit to form a film. In the present embodiment, a film of an even thickness can be formed because the PVD process is carried out while the rotating table 54 is rotated.

Finally, after cooling the inside of the reactor 51, the atmospheric condition is brought back and then the PVD jig 321 is taken out of the reactor 51. Then, the PVD jig 321 is unsecured from the repaired die 1.

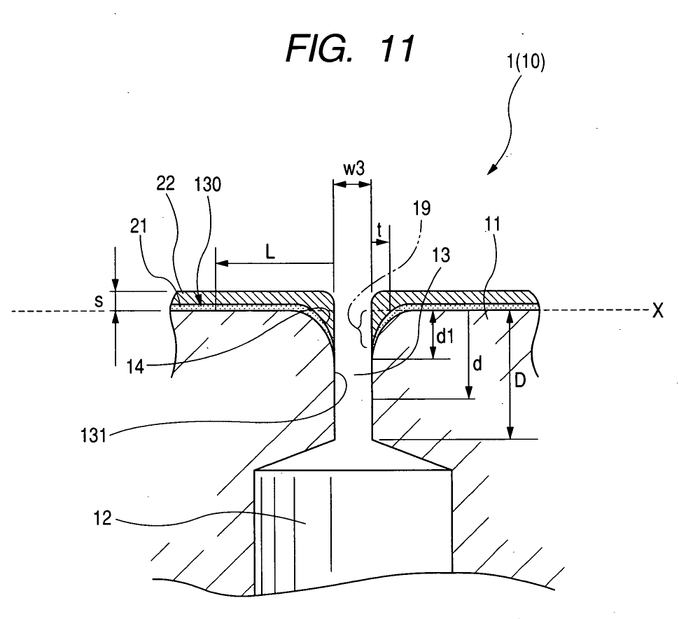

In this way, as shown in FIG. 11, the PVD repairing film 22 is formed on the CVD repairing film 21 that has been formed on the groove-formed surface 130 so as to extend onto each corner 14 to restore the worn-out portion 19.

In the present embodiment, Cr is used for the metal target 52 to carry out the PVD process, and then the metal target 52 is changed to the one made of Ti to again carry out the PVD process. Accordingly, the PVD repairing film 22 is made up of two layers, i.e. a CrN layer and a TiN layer (not shown).

### (3.3 Repaired Die)

The repaired die 1 obtained by the repairing method of the present embodiment is now described.

As shown in FIG. 11, in the die 1 for molding a structure according to the present embodiment, the CVD repairing film 21 formed by carrying out the CVD process is provided on the groove-formed surface 130 formed with the grooves 13 and serving as the end surface of the die body 11, through which a material is extruded, the CVD repairing film 21 extending onto each corner 14 at the intersecting line between the groove-formed surface 130 and the inner side face 131 of each groove 13 to make up for the worn-out portion 19.

Further, the PVD repairing film 22 formed by carrying out the PVD process is provided on the CVD repairing film 21 that has been provided on the groove-formed surface 130 so as to extend onto each corner 14 to make up for the worn-out portion 19. In this way, the worn-out portion 19 at each of the corners 14 can be restored.

As shown in FIG. 11, the width w3 of the groove 13 of the repaired die 1 is 140 μm.

As described above, the CVD repairing film 21 is made up of three layers, i.e. the TiC layer, the TiCN layer and the TiN layer, and has the hardness 2000 HV. As the hardness of the SKD member constructing the die body 11 is 500 HV, the hardness of the CVD repairing film 21 is higher than that of the die body 11 by a factor of 4.

Further, the PVD repairing film 22 is made up of two layers, i.e. the CrN layer and the TiN layer as described above.

The hardness of the CVD repairing film 21 is 2000 HV, which is higher than that of the die body 11 by a factor of 4.

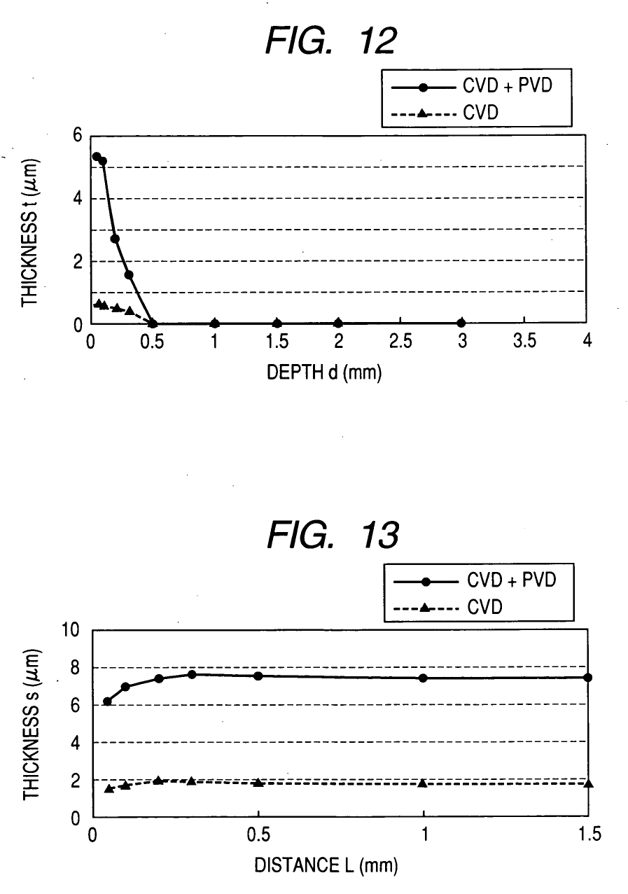

FIG. 12 shows a relation between the depth “d” from the groove-formed surface 130 along the direction in which the groove 13 extends and the total thickness “t” of the two repairing films 21 and 22. FIG. 12 also shows the thickness of the CVD repairing film 21 alone. As shown in FIG. 11, the depth “d” is a distance from the groove-formed surface 130 along the direction of depth of the groove 13, and the thickness “t” is the total thickness of the repairing films 21 and 22 along the direction parallel to the groove-formed surface 130.

As can be seen from FIG. 12, at the position of a depth d=0.5 mm, the thickness of the PVD repairing film 22 is close to “0”. This indicates that the region d1 (refer to FIG. 11) in which the PVD repairing film 22 is formed extends within a length of 0.5 mm. In other words, the PVD repairing film 22 is formed in a region which is equal to or smaller than one tenth of the depth D (=5 mm) of the groove 13. It should be appreciated that the region d1 for forming the PVD repairing film 22 is to extend from the groove-formed surface 130 to the point where the thickness “t” of the PVD repairing film 22 is substantially “0”.

FIG. 13 shows a relation between the distance L from the inner side face 131 of the groove 13 along the direction in which the groove-formed surface 130 extends and the total thickness “s” of the two repairing films 21 and 22. FIG. 13 also shows the thickness of the CVD repairing film 21 alone. As shown in FIG. 11, the distance L is a distance in the direction stepping away from the inner side face 131 of the groove 13. The thickness “s” is the total thickness of the two repairing films 21 and 22 measured with the original groove-formed surface 130 as a reference surface X.

As can be seen from FIG. 13, the total thickness of the repairing films 21 and 22 falls within the range of 6 to 8 μm. Of the total thickness, the thickness of the CVD repairing film 21 occupies a thickness ranging from 1 to 2 μm.

### (3.4 Advantages)

The following is a description on the advantages of the repairing method according to the present embodiment.

In the method for repairing the die 1 for molding a structure according to the present embodiment, the CVD repairing film 21 is formed through the CVD process on the groove-formed surface 130 so as to extend onto each corner 14 to restore the worn-out portion 19. Subsequently, the PVD repairing film 22 is formed through the PVD process on the CVD repairing film 21 that has been formed on the groove-formed surface 130 so as to extend onto each corner 14 to restore the worn-out portion 19. In other words, both of the CVD and the PVD processes are performed on the side of the groove-formed surface 130 which serves as a surface for extruding a material therefrom and plays the most important roll in determining the moldability and dimensional accuracy of a structure, so that both of the CVD repairing film 21 and the PVD repairing film 22 are formed.

In this way, the worn-out portion 19 of each corner 14 can be readily restored with good accuracy. In other words, the life-ended die 1 can be repaired to an extent that the repaired die 1 can mold a structure whose accuracy is equivalent to that of the structure molded by the initial-state die 1.

The two repairing films 21 and 22 formed by both of the processes have high density and high hardness. By forming two such repairing films 21 and 22 on the groove-formed surface 130 for extruding a material so as to extend onto each corner 14 tending to cause abrasion to thereby restore the worn-out portion 19, the repaired die 1 can effectively achieve excellent durability and abrasion resistance.

The CVD repairing film 21 formed by the CVD process exerts high adhesion to the base member (which corresponds to the die body 11 in the present embodiment). Therefore, formation of such a CVD repairing film 21 as a base can much more enhance the durability of the repaired die 1.

The PVD repairing film 22 formed by the PVD process has high film-forming accuracy. Because such a PVD repairing film 22 is formed as an upper layer of the repairing film of the double structure, which is formed on the side of the groove-formed surface 130, dimensional accuracy of the repaired die 1 is ensured to become much higher. Therefore, moldability and dimensional accuracy can be more enhanced in the structure obtained by using the repaired die 1.

The PVD process can readily achieve formation of a thick film. Accordingly, comparing with the conventional case where only the CVD process is used, which is unlikely to achieve formation of a thick film, the method of the present embodiment can readily form a repairing film having a sufficient thickness for restoring the worn-out portion of the die 1. Thus, the repairing process of the die 1 can be performed with efficiency.

In the present embodiment, the CVD repairing film 21 is made up of a multiple layers of TiC, TiCN and TiN. Therefore, the CVD repairing film 21 has high hardness and can enhance adhesion to the die body 11. Thus, the repaired die 1 can achieve sufficient durability and abrasion resistance.

Further, the PVD repairing film 22 is made up of a multiple layers of TiN and CrN. Therefore, the PVD repairing film 22 has high hardness, so that the repaired die 1 may have sufficient durability and abrasion resistance.

Further, the PVD repairing film 22 is formed in a region which is equal to or smaller than one tenth of the depth D of the groove 13 starting from the groove-formed surface 130. Thus, unevenness of the width of each groove 13 can be suppressed in the repaired die 1. Therefore, the dimensional accuracy of the structure molded by using the repaired die 1 can be enhanced.

The hardness of the CVD repairing film 21 and the PVD repairing film 22 is 2000 HV which is higher than that of the die body 11 by a factor of 4. As a result, the two repairing films 21 and 22 exert high hardness, whereby the repaired die 1 may achieve sufficient durability and abrasion resistance.

As described above, by using the method for repairing a die according to the present embodiment, a die for molding a structure can be readily repaired with good accuracy, and thus the repaired die for molding a structure may have excellent durability and abrasion resistance.

### (3.5 Modification)

In the third embodiment, the CVD repairing film 21 has been made up of a multiple layers of TiC, TiCN and TiN. Alternatively, the CVD repairing film 21 may be made up of a single layer of any one of TiC, TiCN and TiN, or may be made up of two layers formed of any combination of two materials among TiC, TiCN and TiN. Further, although the PVD repairing film 22 has been made up of a multiple layers of TiN and CrN in the third embodiment, it may be made up of a single layer made up of either one of TiN and CrN. In any of these alternatives, it is possible to obtain a repairing film having a hardness larger than 500 HV, preferably 750 HV or more, which is a hardness required as a good coating film as described above.

The best moldability and dimensional accuracy of a structure are attained by the groove-formed surface 130, especially, an opening width and shape of the grooves 13 thereon. Accordingly, in repairing a used die, it is essential to provide a repairing film on the groove-formed surface 130 so as to extend onto each corner 14 to restore the worn-out portion 19, assuring the grooves 13 to have the width w3. However, the repairing film may be or may not be provided to the portions other than the groove-formed surface 130. For example, in the repairing method in the third embodiment, the CVD process and the PVD process may be performed without providing a mask as described below.

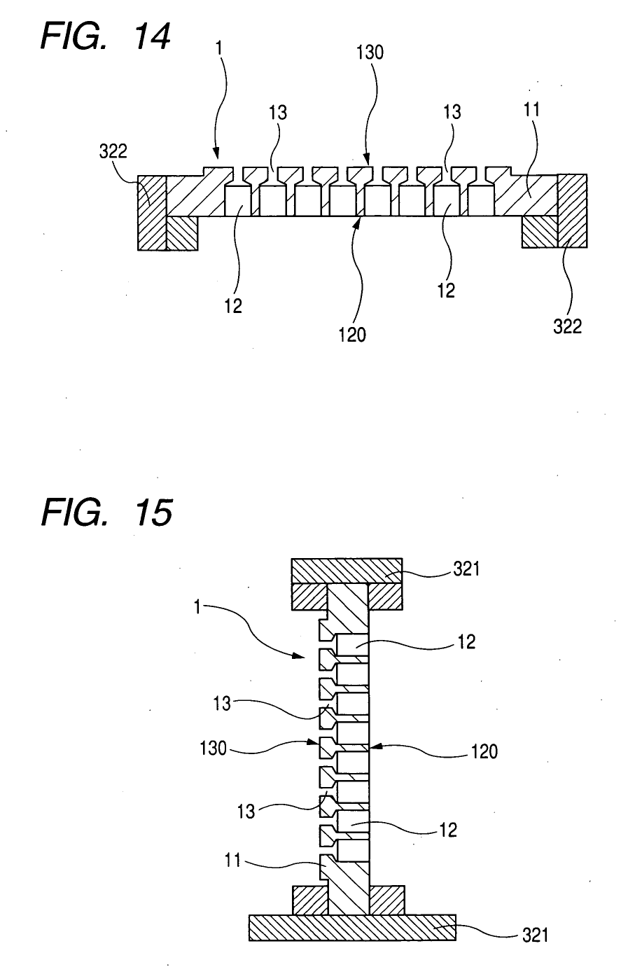

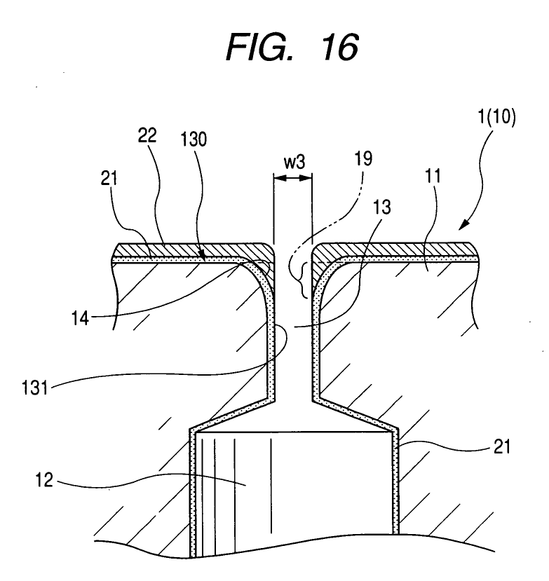

As shown in FIG. 14, in the repairing method of the present modification, the die 1 is secured to the CVD jig 322. Then, by using the CVD apparatus 4 shown in FIG. 10, the CVD process is carried out. Thus, as shown in FIG. 16, the CVD repairing film 21 can be formed over the die body 11.

Subsequently, as shown in FIG. 15, the die 1 is secured to the PVD jig 321. Then, the PVD process is carried out using the PVD apparatus 5 shown in FIG. 5. In this case, in performing the PVD process, a single metal target 52 is provided in the PVD apparatus 5, and the die 1 is set so that the metal target 52 faces the groove-formed surface 130 of the die 1, and further, the die 1 and the metal target 52 are fixedly positioned. Thus, as shown in FIG. 16, the PVD repairing film 22 is formed on the CVD repairing film 21 that has been formed on the groove-formed surface 130 so as to extend onto each corner 14 to restore the worn-out portion 19.

Other procedure, arrangement and advantages are the same as in the third embodiment.

### 4. Lifetime Evaluation

A honeycomb structure was repeatedly formed using a repaired die 10 obtained through the methods of the first, the second and the third embodiments to evaluate the lifetime of the dies.

### (4.1 Samples for Comparative Evaluation)

As the inventive articles, the die 10 repaired by the PVD process according to the first embodiment (Inventive Article E1), the die 10 repaired by the CVD process according to the second embodiment (Inventive Article E2) and the die 10 repaired by both the CVD process and the PVD process according to the third embodiment (Inventive Article E3) were prepared. As comparative articles, an unused initial die with no treatment (Comparative Article C1) was prepared. In all of these dies, the width of the groove 13 was set at 140 μm.

### (4.2 Procedure for Evaluation)

The procedure of evaluation is as follows.

Using the dies 10 of Inventive Articles E1, E2 and E3, extrusion was performed using a material containing cordierite ceramic to form honeycomb structures. The molded honeycomb structures each had a cylindrical shape with a diameter 100 mm and a length 90 mm. Extrusion was repeatedly performed. When the width of the groove 13 in the groove-formed surface 130 became 150 μm or more, the die was determined to have ended its lifetime. The same procedure was taken as to Comparative Article C1. The number of honeycomb structures produced by each die up to the end of its lifetime was counted. A production ratio of each of Inventive Articles E1, E2 and E3 was calculated with the number of honeycomb structures produced by using Comparative Article C1 as a reference production ratio “1”.

### (Evaluation Results)

Results of the evaluation are shown in FIG. 17.

As can be seen from the figure, the production ratio of Inventive Article E1 repaired by the PVD process was twice as high as that of unused/unprocessed Comparative Article C1. Further, the production ratios of Inventive Article E2 repaired by the CVD process and Inventive Article E3 repaired by both of the PVD process and the CVD process were each three times as high as that of Comparative Article C1. In other words, it can be seen that Inventive Articles E1, E2 and E3 each exerted quite excellent durability and abrasion resistance and the die's lifetime was longer.

### 5. Further Modification

As described above, the production ratios of Inventive Articles E1, E2 and E3 are each higher than that of Comparative Article C1 by a factor of 2 or 3.

Accordingly, dies may be manufactured employing the repairing method of the present invention. Specifically, Comparative Article C1 may be provided with etching or grinding treatment (also referred as pre-treatment) first, for example, to purposely form a die having the worn-out portion 19 whose worn-out degree is substantially the same as that of the dies repaired through the methods of the first, second and third embodiments and the modification. Subsequently, the repairing method of the first, second or third embodiment may be performed for the resultant etched or grinded die. This procedure may be applied as a method for manufacturing a die (i.e. surface treatment method for forming grooves in a die), and a die manufactured in this way may exert excellent durability and abrasion resistance.

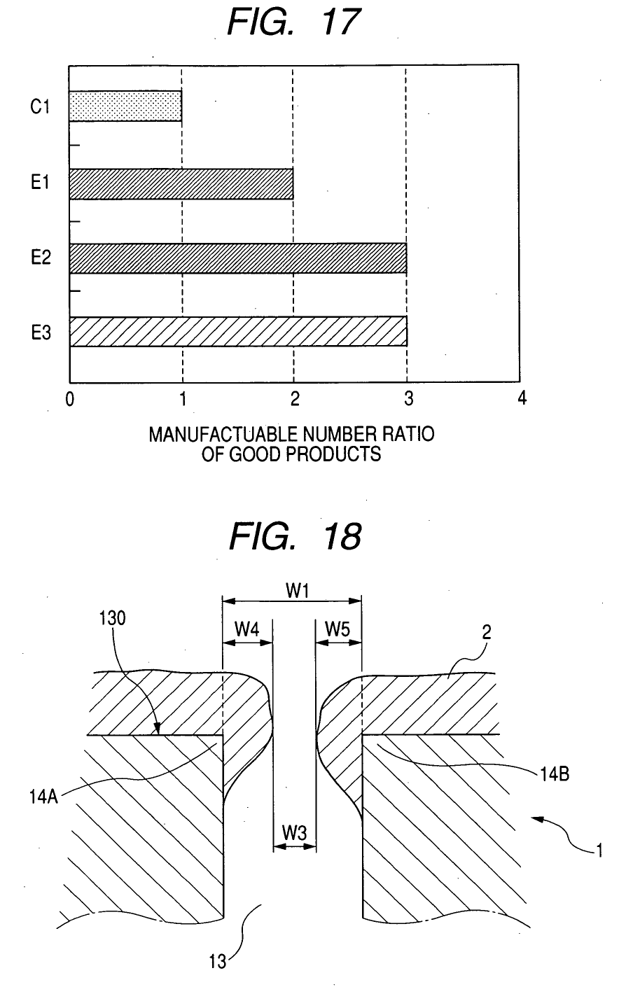

As shown in FIG. 18, from the manufacturing process view, the pre-treatment, namely a rounding process for rounding an original sharp corner 14A and 14B, contributes to ensure dimensional accuracy in an opening width w1 of the groove 13.

Namely, if the film 2 is formed on the Article C1 which has the original sharp corners 14A and 14B, an overhang w4 and w5 will be formed. These overhangs cause a dimensional error (i.e., w1−w3=w1−w4−w5) in the opening width of the groove. This dimensional error degrades durability of a processed die and dimensional accuracy of the structural body manufactured by using the processed die. In contrast, the film 2 formed on the Article C1 which is pre-treated and has a rounding corner, similar to the corner 14 shown in FIGS. 3, 6, and 11, hardly forms an overhang similar to the overhang w4 and w5. In this way, forming a rounded corner before forming a film thereon is preferable so as to manufacture a die with good durability and accuracy and be capable of mass-producing accurate structural bodies.

Further, this manufacturing method, and dies manufactured using this manufacturing method should have all the advantages obtained in the first, second and third embodiments and the modification.

In order to explain the manner in which the present invention exerts advantages, a specific method for repairing a used die and a specific repaired die repaired thereby have been described above. It will be appreciated, however, that the present invention is not limited to these methods and repaired dies, but any and all modifications, variations or equivalents, which may occur to those who are skilled in the art, should be considered to fall within the scope of the present invention.

What is claimed is:

1. A method for repairing a used extrusion die being used to form a structural body, the die having a first surface, a lattice-shaped groove thereon, a through-hole which communicates with the groove, and a worn-out corner where the first surface crosses an inner wall of the groove, the method comprising steps of;
supplying a material to the first surface; and
forming a film on the worn-out corner with the material.

2. The method recited in claim 1, wherein the forming step forms the film on the inner wall to reach a depth less than one tenth depth of the groove from a level of the first surface.

3. The method recited in claim 1, wherein the forming step is performed using a physical vapor deposition (PVD) process.

4. The method recited in claim 3, further comprising a masking step before the supplying step, the masking step masking a second surface which communicates the hole.

5. The method recited in claim 3, wherein the forming step forms a single-layered film or a multi-layered film composed of CrN and/or TiN.

6. The method recited in claim 1, wherein the forming step is performed using a chemical vapor deposition (CVD) process.

7. The method recited in claim 6, further comprising a masking step before the supplying step, the masking step masking a second surface which communicates the hole.

8. The method recited in claim 6, wherein the forming step forms a single-layered film or a multi-layered film composed of at least one selected from the group consisting of TiC, TiCN, and TiN.

9. The method recited in claim 1, wherein the forming step comprises;
first forming step for forming a first film using a chemical vapor deposition process; and
second forming step for forming a second film on the first film using a physical vapor deposition process.

10. A method for manufacturing an extrusion die which is used to extrusion-mold a structural body, the die having an surface with a groove thereon, a through-hole communicating with the groove, and a corner where the surface crosses a wall of the groove, the method comprising;
rounding for rounding the corner; and
forming for forming a film on a rounded corner rounded by the rounding step.

11. A die for extrusion-molding a structural body comprising:
a surface with a groove thereon;
a through-hole communicating with the groove;
a rounded corner of the die, the corner where the surface crosses a wall of the groove; and
a film being formed on the corner.

12. The die recited in claim 11, wherein the film reaches a depth less than one tenth depth of the groove from the surface.

13. The die recited in claim 11, wherein the film is a single-layered film or a multi-layered film composed of at least one selected from the group consisting of TiN, CrN, TiC, TiCN, and TiN.

14. The die recited in claim 11, wherein hardness of the film is harder than hardness of the body.

15. The die recited in claim 11, wherein hardness of the film is equal to or one and half harder than hardness of the body.

16. The die recited in claim 11, wherein hardness of the film is harder than 500 HV.

17. The die recited in claim 11, wherein hardness of the film is equal to or harder than 750 HV.
